(19) United States
(12) Patent Application Publication
(10) Pub. No.: US 2026/0132539 A1
(43) Pub. Date: May 14, 2026

(54) GROUP III NITRIDE SINGLE CRYSTAL GROWTH METHOD

(71) Applicant: TOYODA GOSEI CO., LTD., Kiyosu-shi (JP)

(72) Inventors: Taku FUJIMORI, Kiyosu-shi (JP); Miki MORIYAMA, Kiyosu-shi (JP)

(21) Appl. No.: 19/384,613

(22) Filed: Nov. 10, 2025

(30) Foreign Application Priority Data
Nov. 13, 2024 (JP) 2024-198125

(51) Int. Cl. C30B 19/02; C30B 19/12; C30B 29/40

(52) U.S. Cl. CPC C30B 19/02; C30B 19/12; C30B 29/406

(57) ABSTRACT

A Group III nitride single crystal growth method includes: preparing an alkali metal melt from which an oxygen atom has been removed; preparing a seed substrate in which a plurality of seed crystals made from a Group III nitride semiconductor are formed in a dot shape on a substrate; forming an initial nucleus on the seed crystal by bringing a mixed liquid containing the alkali metal melt and a Group III metal molten liquid into contact with a surface of the seed crystal in an atmosphere containing nitrogen; and growing a Group III nitride single crystal from the initial nucleus by bringing the mixed liquid into contact with the initial nucleus in an atmosphere containing nitrogen.

### CROSS-REFERENCE TO RELATED APPLICATION

This application is based on and claims priority under 35 USC 119 from Japanese Patent Application No. 2024-198125 filed on November 13, 2024.

### TECHNICAL FIELD

The present invention relates to a Group III nitride single crystal growth method.

### BACKGROUND ART

Conventionally, there has been known a flux method in which a GaN single crystal is grown on a GaN substrate by immersing the GaN substrate in a Ga-Na mixed melt stored in a crucible. However, when an oxygen atom is contained in the mixed melt, miscellaneous crystals are generated inside the crucible, which decreases crystallinity of the GaN single crystal. In order to prevent such a decrease in crystallinity, Patent Literature 1 discloses a configuration in which a liquid Na material as a raw material of the mixed melt is circulated between a high temperature state and a low temperature state by using a Na circulation device to precipitate and remove an oxygen atom as Na₂O.

Patent Literature 1: JP2023-001346A

### SUMMARY OF INVENTION

However, Patent Literature 1 does not disclose a configuration in which a GaN single crystal having a high crystal quality is grown from various seed crystals using an MPS (multipoint seed) substrate, which is a substrate in which a plurality of dot-shaped seed crystals are periodically arranged. In addition, in the case where the MPS substrate is used, sizes or shapes of nuclei formed in the seed crystals on the MPS substrate are non-uniform, and there is a new problem that cracks or defects are generated in an initial nucleus or a Group III nitride single crystal grown on the initial nucleus, but this point is not disclosed in Patent Literature 1. With respect to this, it is conceivable to increase a degree of supersaturation of N (nitrogen) in the mixed liquid by setting a low temperature and a high pressure to promote nucleation in the seed crystal on the MPS substrate, but in this case, there is a new problem that miscellaneous crystals are generated and the crystal quality decreases.

The present invention has been made in view of such problems, and an object thereof is to provide a Group III nitride single crystal growth method capable of forming a Group III nitride single crystal having a high crystal quality using an MPS substrate.

One aspect of the present invention relates to a Group III nitride single crystal growth method including: an alkali metal melt preparation step of preparing an alkali metal melt from which an oxygen atom has been removed; a seed substrate preparation step of preparing a seed substrate in which a plurality of seed crystals made of a Group III nitride semiconductor are formed in a dot shape on a substrate; an initial nucleus formation step of forming an initial nucleus on the seed crystal by bringing a mixed liquid containing the alkali metal melt and a Group III metal molten liquid into contact with a surface of the seed crystal in an atmosphere containing nitrogen; and a crystal growth step of growing a Group III nitride single crystal from the initial nucleus by bringing the mixed liquid into contact with the initial nucleus in an atmosphere containing nitrogen.

In the Group III nitride single crystal growth method according to the above aspect, an MPS substrate in which the Group III nitride semiconductor is formed in a plurality of dots on the substrate is used, the Group III nitride semiconductor on the MPS substrate is used as the seed crystal, the mixed liquid containing the alkali metal melt from which the oxygen atom has been removed and the Group III metal molten liquid is brought into contact with the surface of the seed crystal to form the initial nucleus on the seed crystal, and then the Group III nitride single crystal is grown from the initial nucleus. Accordingly, since the alkali metal melt from which the oxygen atom has been removed is used, a degree of supersaturation of N (nitrogen) in the mixed liquid can be increased without setting a low temperature and a high pressure, and nucleation in the seed crystal on the MPS substrate can be promoted while preventing generation of miscellaneous crystals. As a result, sizes or shapes of the generated initial nuclei can be made uniform, so that the generation of cracks or defects in the initial nuclei or the Group III nitride single crystal grown on the initial nuclei is prevented, and a crystal quality can be improved.

As described above, according to the above aspect, it is possible to provide a Group III nitride single crystal growth method capable of forming a Group III nitride single crystal having a high crystal quality using an MPS substrate.

### BRIEF DESCRIPTION OF DRAWINGS

FIG. 1 is a flowchart showing a Group III nitride single crystal growth method according to a first embodiment.

FIG. 2 is a conceptual diagram showing a configuration of a Na circulation device in the first embodiment.

FIG. 3 is a figure including (a) a conceptual diagram of a seed substrate on which a plurality of seed crystals are formed, (b) a conceptual diagram of a seed substrate on which a plurality of initial nuclei are formed, (c) a conceptual diagram showing a state where a GaN single crystal is formed between the plurality of initial nuclei, and (d) a conceptual diagram showing a state where a GaN single crystal is grown on a flattened crystal surface, according to the first embodiment.

FIG. 4 is a plan view showing a configuration of the seed substrate according to the first embodiment.

FIG. 5 is a cross-sectional view showing a configuration of the seed crystal according to the first embodiment, which is a cross-sectional view perpendicular to a substrate main surface.

FIG. 6 is a plan view showing a configuration of the seed crystal according to the first embodiment.

FIG. 7 is a conceptual diagram showing a state where the seed substrate is not immersed in a mixed melt in the first embodiment.

FIG. 8 is a conceptual diagram showing a state where the seed substrate is formed in the mixed melt in the first embodiment.

FIG. 9 is a top view of a jig and a crucible in the first embodiment.

FIG. 10 is a figure including (a) a diagram showing a growth state of an initial nucleus in a test example, and (b) a diagram showing a growth state of an initial nucleus in a comparative example in a checking test.

### DESCRIPTION OF EMBODIMENTS

It is preferable that, in the alkali metal melt preparation step, the alkali metal melt is circulated through a first region held at a first temperature and a second region held at a second temperature lower than the first temperature, to remove the oxygen atom from the alkali metal melt in the second region. In this case, the oxygen atom can be efficiently removed from the alkali metal melt.

It is preferable that, in the alkali metal melt preparation step, a concentration of the oxygen atom in the alkali metal melt is controlled by controlling the second temperature. In this case, since the concentration of the oxygen atom in the alkali metal melt can be maintained at a low concentration, the nucleation in the seed crystal on the MPS substrate is further promoted while preventing the generation of miscellaneous crystals, and the uniformity of sizes or shapes of initial nuclei to be generated can be further promoted. As a result, the crystal quality can be further improved.

It is preferable that, the second temperature is controlled in a range of 120°C or higher and 300°C or lower, and the first temperature is controlled to a temperature higher than the second temperature. In this case, the generation of miscellaneous crystals can be further prevented while maintaining fluidity of the alkali metal melt, and the crystal quality of the Group III nitride single crystal to be formed can be further improved.

An oxygen concentration in the alkali metal melt is preferably 30 ppm or less. In this case, since the oxygen concentration in the alkali metal melt is sufficiently low, the generation of miscellaneous crystals can be further prevented and the crystal quality of the Group III nitride single crystal to be formed can be further improved.

In the seed substrate preparation step, a diameter of the seed crystal formed on the substrate is preferably within a range of 30 μm to 300 μm. In this case, a Group III nitride single crystal with little dislocation and warpage can be formed, an area of a side surface of the seed crystal can be increased, and the growth of the initial nucleus from the side surface can be facilitated. In addition, when the diameter of the seed crystal is within the above range, the Group III nitride single crystal and the seed crystal portion are easily separated after the growth of the Group III nitride single crystal, and thus a seed crystal portion including the MPS substrate is easily separated from the Group III nitride single crystal.

### First Embodiment

### 1. Overview of Flux Method

A Group III nitride single crystal growth method according to a first embodiment is a method for growing a Group III nitride single crystal by using a flux method. Accordingly, a Group III nitride semiconductor is produced. The flux method is a method for epitaxially growing a Group III nitride semiconductor in a liquid phase by supplying and melting a nitrogen-containing gas to a mixed melt containing an alkali metal to be a flux and a Group III metal as a raw material.

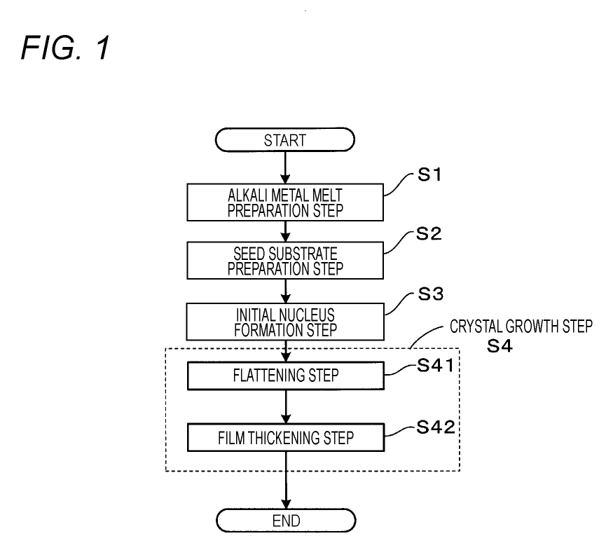

As shown in FIG. 1, the Group III nitride single crystal growth method according to the first embodiment includes an alkali metal melt preparation step S1, a seed substrate preparation step S2, an initial nucleus formation step S3, and a crystal growth step S4. The crystal growth step S4 includes a flattening step S41 and a film thickening step S42. Hereinafter, each step will be described in detail.

### 2. Alkali Metal Melt Preparation Step S1

In the alkali metal melt preparation step S1, an alkali metal melt from which an oxygen atom has been removed is prepared. The alkali metal melt is obtained by melting an alkali metal to be a flux. The alkali metal may be Na, Li, K, or the like, and in the present embodiment, Na is used as the alkali metal.

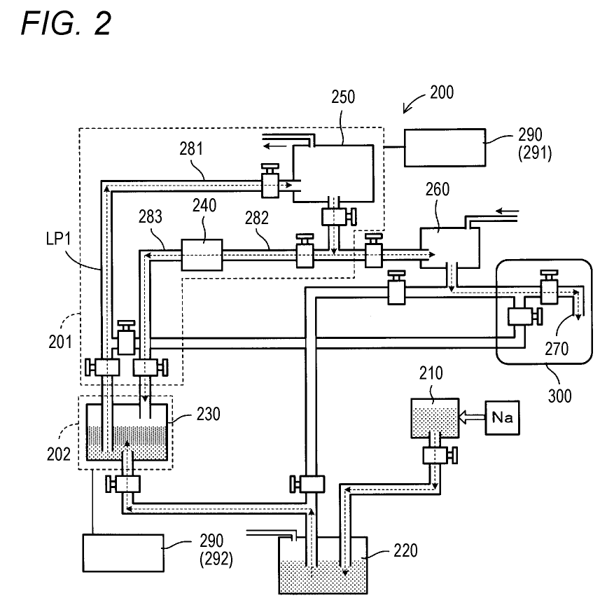

In the present embodiment, in the alkali metal melt preparation step S1, as shown in FIG. 2, the alkali metal melt is circulated through a first region 201 maintained at a first temperature and a second region 202 maintained at a second temperature lower than the first temperature. The alkali metal melt can be circulated by using a Na circulation device 200 shown in FIG. 2. The Na circulation device 200 is a device that controls a purity of Na while circulating Na. The Na circulation device 200 is connected to a glove box 300. Therefore, a Na material whose purity is increased by the Na circulation device 200 can be supplied into the glove box 300. The Na material is supplied to the glove box 300 whose dew point and atmosphere are controlled. Therefore, the Na material supplied to the glove box 300 is prevented from reacting with oxygen and moisture.

The Na circulation device 200 includes a supply tank 210, a dump tank 220, a cold trap 230, an electromagnetic pump 240, an expansion tank 250, a measurement tank 260, a Na collection port 270, and pipes 281, 282, and 283. In the present embodiment, the first region 201 includes the electromagnetic pump 240, the expansion tank 250, the measurement tank 260, and the pipes 281, 282, and 283, and the second region 202 includes the cold trap 230. In addition, the Na circulation device 200 includes other pipes, valves, and a heating device 290 that heats each part.

The Na circulation device 200 has a circulation path LP1 through which the Na material flows in a liquid state. The circulation path LP1 includes the cold trap 230, the expansion tank 250, the electromagnetic pump 240, and the pipes 281, 282, and 283.

The supply tank 210 is a tank for supplying an initial Na material to the Na circulation device 200. The initial Na material is a high purity Na material to some extent, but contains a trace amount of impurities. The initial Na material is a solid. Since the supply tank 210 is heated, the Na material becomes a liquid. Then, the liquid Na material is sent to the dump tank 220.

The dump tank 220 can absorb a reflected shock wave.

The cold trap 230 is for removing impurities in the Na material. The cold trap 230 also serves as a Na purity control unit that removes or adds impurities such as oxygen. Details of the cold trap 230 will be described later.

The electromagnetic pump 240 returns the Na material from the expansion tank 250 to the cold trap 230. The Na circulation device 200 purifies the Na material by circulating the Na material between the cold trap 230 and the expansion tank 250.

The expansion tank 250 is a Na storage unit for temporarily storing the Na material from which impurities and the like have been removed by the cold trap 230.

The measurement tank 260 measures an amount of the Na material taken out of the Na collection port 270. The purity of the Na material stored in the measurement tank 260 is sufficiently high.

The Na collection port 270 is a supply port for supplying the purified Na material to the glove box 300.

The heating device 290 heats each part of the Na circulation device 200 to a predetermined temperature. The heating device 290 includes a first heating device 291 and a second heating device 292, the first heating device 291 can maintain the first temperature, which is the temperature of the first region 201, at a set temperature, and the second heating device 292 can maintain the second temperature, which is the temperature of the second region 202, at a set temperature.

### 2-1. Operation of Na Circulation Device

In the alkali metal melt preparation step S1, first, the solid Na material is supplied to the supply tank 210 of the Na circulation device 200. The Na material is heated by the supply tank 210 and becomes a liquid Na material. The liquid Na material is sent to the dump tank 220. Then, the liquid Na material is gradually sent from the dump tank 220 to the circulation path LP1. The liquid Na material circulates through the circulation path LP1.

Here, the higher the temperature of the Na material, the higher the solubility of oxygen in the Na material. The cold trap 230 included in the second region 202 is a portion having the lowest temperature in the circulation path LP1. Therefore, for example, Na₂O is precipitated at the cold trap 230. Na₂O may be removed by using a filter or the like.

The liquid Na material alternately repeats two states of a high temperature state in the first region 201 and a low temperature state in the second region 202 while circulating through the circulation path LP1. Therefore, Na₂O is precipitated in a low temperature state, and oxygen is repeatedly removed from the liquid Na material. As a result, the Na material having a high purity is purified. The Na material supplied from the Na collection port 270 is a liquid. The liquid Na material is poured into a container inside the glove box 300. The liquid Na material is cooled in the container to be a solid.

### 2-2. Temperature Setting in First Region 201 and Second Region 202

As described above, the temperature of the first region 201 is the first temperature, the temperature of the second region is the second temperature, and the second temperature is lower than the first temperature. The first temperature and the second temperature are both higher than a melting point (about 98°C) of Na and lower than a boiling point (890°C) of Na. The second temperature can be 120°C or higher and 300°C or lower, and preferably 150°C or higher and 180°C or lower. In the case where the second temperature is lower than 120°C, the temperature is close to the melting point of Na, so that the fluidity of the Na material decreases, which is not preferred. In the case where the second temperature is higher than 300°C, the solubility of oxygen in Na is increased, so that Na₂O is less likely to precipitate, and the amount of oxygen removed from the Na material is reduced. Note that, the first temperature of the first region 201 is sufficiently a temperature equal to or higher than the second temperature and lower than the boiling point of Na.

As described above, since the solubility of oxygen in the Na material depends on the temperature of the Na material, the concentration of the oxygen atom in a reaction liquid made of the Na material can be controlled by controlling the second temperature. For example, the oxygen concentration in the reaction liquid can be 30 ppm or less by setting the second temperature to 120°C or higher and 300°C or lower, the oxygen concentration in the reaction liquid can be 10 ppm or less by setting the second temperature to 120°C or higher and 180°C or lower, and the oxygen concentration in the reaction liquid can be 3 ppm or less by setting the second temperature to 120°C or higher and 150°C or lower. Therefore, the second temperature is preferably 150°C or higher and 180°C or lower, and accordingly, the oxygen concentration in the reaction liquid can be reduced while maintaining the fluidity of the Na material.

In the present embodiment, the expansion tank 250 and the pipes 281, 282, and 283 therearound, which serve as the first region 201, are maintained at a first temperature of 200°C or higher and 300°C or lower by the first heating device 291, and the cold trap 230 serving as the second region 202 is maintained at a second temperature of 150°C or higher and 180°C or lower by the second heating device 292. Accordingly, the oxygen atom in the Na material can be removed by the cold trap 230. In addition, other impurities can also be removed. The Na material from which the oxygen atom or the like has been removed is supplied from the Na collection port 270 to the glove box 300 and prepared as a reaction liquid, whereby the alkali metal melt preparation step S1 is completed. Note that, a pressure in the glove box 300 is slightly higher than 1 atm since an Ar gas is supplied.

### 3. Seed Substrate Preparation Step S2

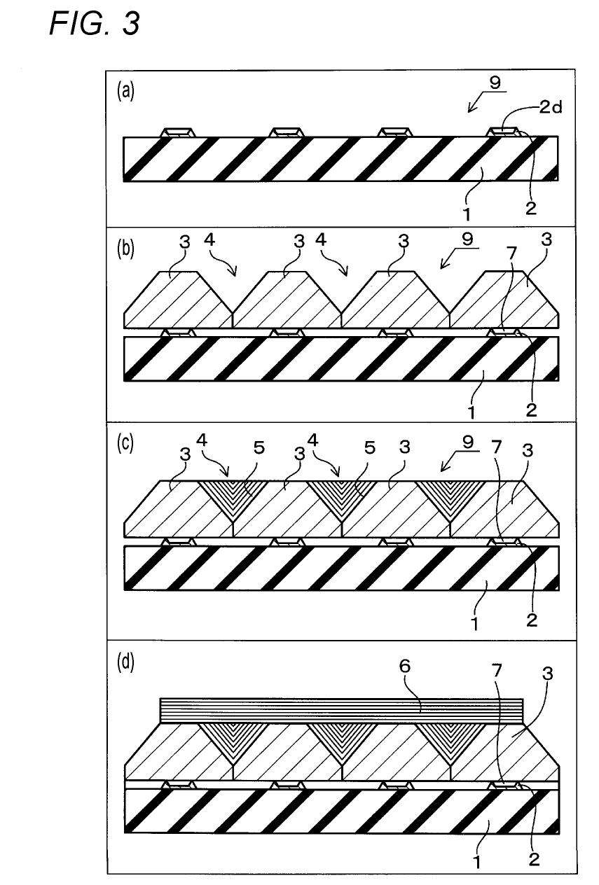

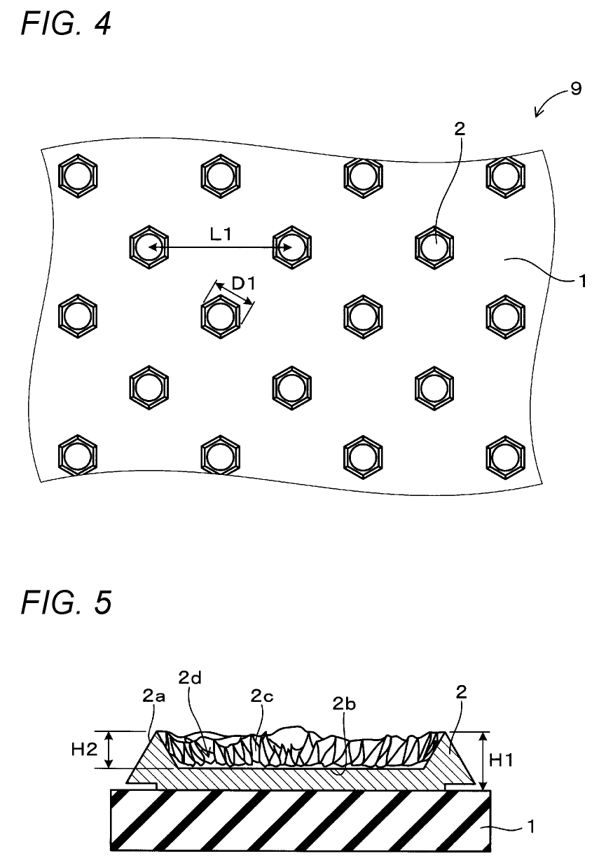

In the seed substrate preparation step S2 shown in FIG. 1, a seed substrate 9 shown in (a) of FIG. 3 is prepared. The seed substrate 9 is a multipoint seed (MPS) substrate in which a plurality of dot-shaped seed crystals 2 are periodically arranged on a substrate 1. (a) of FIG. 3 is a cross-sectional view of the seed substrate 9, the cross section being perpendicular to a substrate main surface. FIG. 4 is a plan view of the seed substrate 9 as viewed from above.

As the substrate 1, a Group III nitride semiconductor, sapphire, aluminum oxynitride, SiC, Si, spinel, ZnO, gallium oxide, or the like can be used. In the case of a sapphire substrate, it is, for example, a substrate having a c plane or a plane as a main surface.

The plurality of seed crystals 2 are provided on the substrate 1 via a buffer layer (not shown). The seed crystals 2 are arranged in a regular triangular lattice pattern. The buffer layer and the seed crystal 2 are each a Group III nitride semiconductor having any composition such as GaN, AlGaN, and AlN. A material of the buffer layer is appropriately selected depending on a material of the seed crystal 2. For example, in the case where the seed crystal 2 is GaN, the buffer layer is preferably GaN. The material of the seed crystal 2 is usually a Group III nitride semiconductor having a composition same as that of the Group III nitride semiconductor to be grown by using the flux method. The seed crystal 2 may be grown by any method such as a MOCVD method, a HVPE method, or a MBE method, and the MOCVD method or the HVPE method is preferred in terms of crystallinity, a growth time, and the like.

The seed crystals 2 are arranged in a regular triangular lattice pattern as shown in FIG. 3. It is not limited to a regular triangular lattice shape and is any as long as it is a periodic array. A pattern having high symmetry such as a square lattice shape or a regular triangular lattice shape is preferred. Group III nitride semiconductors grown from respective seed crystals 2 can be uniformly combined, and a Group III nitride semiconductor having less dislocation and warpage can be grown. In the case of a regular triangular lattice pattern, an arrangement direction thereof preferably coincides with an a-axis direction or an m-axis direction of the seed crystal 2. Coincidence here does not mean complete coincidence, and a deviation of an angle of about 10 degrees is allowed as an error. The deviation of the angle is preferably 1 degree or less.

A distance L1 between centers of the adjacent seed crystals 2 is preferably 100 μm to 2000 μm. Within this range, a Group III nitride semiconductor having less dislocation and warpage can be grown. The distance L1 is more preferably 200 μm to 1500 μm, and still more preferably 300 μm to 1000 μm.

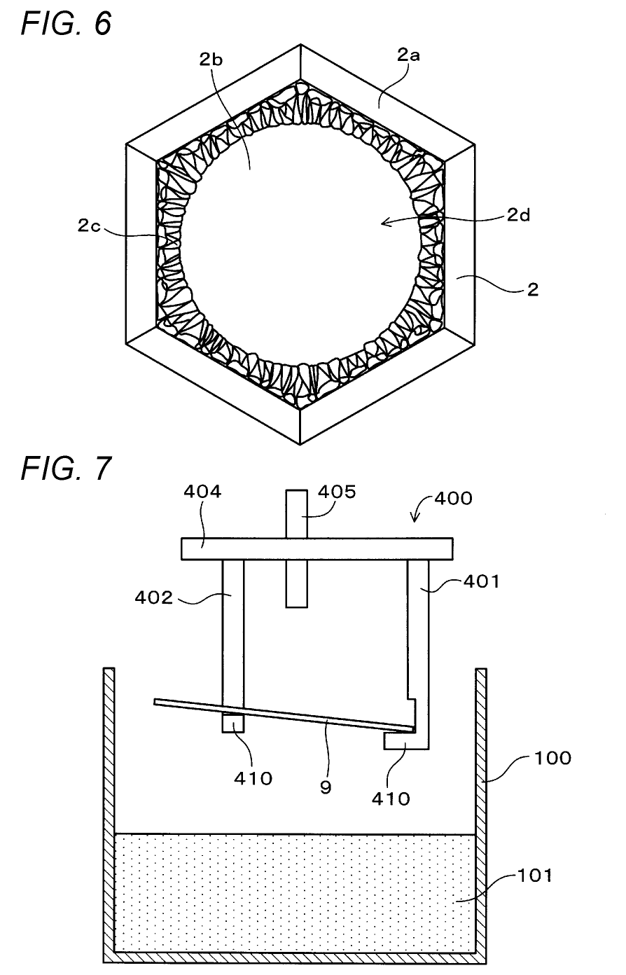

Next, the shape of the seed crystal 2 will be described in detail. FIG. 5 is a cross-sectional view showing a configuration of the seed crystal 2, which is a cross-sectional view perpendicular to the substrate main surface. FIG. 6 is a plan view showing the configuration of the seed crystal 2. As shown in FIGS. 5 and 6, the seed crystal 2 has a disk portion having a disk shape and a regular hexagonal truncated pyramid portion having a regular hexagonal truncated pyramid shape located on and in contact with the disk portion, and has a shape in which a recess 2d is provided at a center of the regular hexagonal truncated pyramid portion.

As to be described later, the seed crystal 2 is formed by selective growth using a mask, and the crystal is laterally grown from an opening of the mask. The mask has a circular opening pattern. Therefore, the mask opening portion remains in a disk shape after the mask is removed. The remaining portion is the disk portion. A shape of the disk portion is equal to a shape of the mask opening when the seed crystal 2 is selectively grown. A diameter D1 of the regular hexagonal truncated pyramid portion is larger than a diameter of the disk portion. Since the disk portion is circular in a plan view, when the substrate 1 is separated after the GaN single crystal is grown by using the flux method, a stress can be dispersed, and the generation of cracks in the grown crystal can be prevented. Note that, depending on the opening pattern of the mask, a shape such as a regular hexagonal plate may be used instead of the disk portion, but a disk is preferred from the viewpoint of dispersing a stress as described above.

A bottom surface of the regular hexagonal truncated pyramid portion of the seed crystal 2 is a regular hexagon. In particular, a regular hexagon in which each side is aligned with an m plane of the seed crystal 2 (each side coincides with the a-axis direction) is preferred. Since the Group III nitride semiconductor is hexagonal, Group III nitride semiconductors grown from regular hexagonal truncated pyramid portions of respective seed crystals 2 can be uniformly combined by forming a regular hexagon. However, it is not necessary to completely coincide with the a-axis, and a deviation of an angle of about 10 degrees is allowed. The deviation of the angle is preferably 1 degree or less.

Six side surfaces 2a of the regular hexagonal truncated pyramid portion of the seed crystal 2 are a (10-11) plane of the Group III nitride semiconductor. The (10-11) plane is a stable plane in the mixed melt in the Na flux method. Therefore, an initial nucleus 3 to be described later grows from the side surface 2a of the regular hexagonal truncated pyramid portion of the seed crystal 2 while maintaining the (10-11) plane. As a result, shapes of the initial nuclei 3 can be made uniform. Note that, the entire side surface 2a does not need to be the (10-11) plane, but it is preferable that 95% or more of the entire side surface 2a is the (10-11) plane. The (10-11) plane referred to here also includes a plane forming an angle of -5 degrees to 5 degrees with respect to the (10-11) plane as an error.

In the present embodiment, the diameter D1 of the regular hexagonal truncated pyramid portion of the seed crystal 2 (a diameter of a circumscribed circle in a plan view) is defined as the diameter D1 of the seed crystal 2, and the diameter D1 of the seed crystal 2 is preferably 30 μm to 300 μm. Within this range, a Group III nitride semiconductor having less dislocation and warpage can be grown. In addition, an area of the side surface 2a of the regular hexagonal truncated pyramid portion of the seed crystal 2 can be increased, and the growth of the initial nucleus 3 from the side surface 2a can be facilitated. The diameter D1 of the seed crystal 2 is more preferably 100 μm to 200 μm.

A height H1 of the seed crystal 2 is preferably 30 μm or more. Within this range, the area of the side surface 2a can be sufficiently increased, and the crystal can be uniformly grown from each side surface 2a. As a result, the shapes of the initial nuclei 3 grown from the respective seed crystals 2 can be made uniform. However, when the height H1 is too high, there is a problem that it takes time to form the seed crystal 2, and thus, it is preferable to set the height H1 to 100 μm or less. The height H1 is more preferably 20 μm to 60 μm, and still more preferably 30 μm to 50 μm.

For the same reason as above, the height H1 of the seed crystal 2 is preferably 0.01 to 0.6 times the diameter D1 of the seed crystal 2. It is more preferably 0.1 to 0.35 times, and still more preferably 0.15 to 0.3 times.

The recess 2d is provided at the center of the seed crystal 2. When the recess 2d is provided, as shown in (a) and (b) of FIG. 3, the recess 2d is not filled with the initial nucleus 3 grown from the seed crystal 2 in the initial nucleus formation step S3 to be described later, and a void 7 (see (b) of FIG. 3) is formed. By forming the void 7, the dislocation of the seed crystal 2 can be prevented from propagating to an upper portion, and a high quality GaN single crystal can be grown.

As shown in FIG. 5, a bottom surface 2b of the recess 2d is flat and is a (0001) plane (c plane) of the Group III nitride semiconductor. The bottom surface 2b is approximately circular in a plan view. Note that, the bottom surface 2b does not need to be flat and may have irregularities. In addition, the shape of the bottom surface 2b in a plan view does not need to be circular.

A side surface 2c of the recess 2d is formed with a large number of irregularities, and has an inclination of approximately the same as that of the (10-11) plane as a whole. When the side surface 2c has such an irregular shape, the side surface 2c serves as a starting point of crystal growth of the Group III nitride semiconductor, and the upper portion of the seed crystal 2 can be likely to be filled with the Group III nitride semiconductor. Note that, the side surface 2c may be a flat surface.

A depth H2 of the recess 2d is preferably 10 μm to 100 μm. Within such a range, the void 7 is more likely to be formed, and a higher quality Group III nitride semiconductor can be grown. The depth H2 is more preferably 20 μm to 60 μm, and still more preferably 30 μm to 50 μm. For the same reason, the depth H2 of the recess 2d is preferably 0.3 to 1.0 times, and more preferably 0.6 to 0.8 times the height H1 of the seed crystal 2.

A diameter of an upper surface of the recess 2d is in a range in which an upper surface of the seed crystal 2 is not present, and the side surface 2c of the recess 2d and the side surface 2a of the seed crystal 2 are connected to each other at an angle. Therefore, the c plane is not present in the upper portion of the seed crystal 2. There is a possibility that the c plane is melted back in the mixed melt in the Na flux method, which causes a variation in shape of respective initial nuclei 3. In addition, there is a possibility that the dislocation of the seed crystal 2 is propagated to the upper portion by the crystal growth from the c plane. Therefore, when a shape in which the c plane is not present in the upper portion is used, it is possible to prevent the variation in shape of the respective initial nuclei 3, and to prevent the propagation of the dislocation of the seed crystal 2 to the upper portion.

In the seed substrate preparation step S2, the seed substrate 9 can be prepared, for example, as follows. First, a mask having a plurality of openings is formed on the substrate 1. The plurality of openings are arranged in a regular triangular lattice pattern. The opening has a circular shape. The shape may be a shape other than a circular shape, such as a regular hexagon, but is preferably a circular shape as in the embodiment in order to form the disk portion and prevent cracks during substrate peeling. A material of the mask may be any material as long as it can prevent the growth of the Group III nitride semiconductor on the mask, and is, for example, SiO₂.

Next, the buffer layer (not shown) and the seed crystal 2 are sequentially selectively grown on the substrate 1 exposed to the opening by a method such as a MOCVD method or a HVPE method. Next, the mask is removed by melt back using hydrofluoric acid or the like. With the above, the seed substrate 9 can be prepared.

Here, when the seed crystal 2 is selectively grown from the opening of the mask, the Group III nitride semiconductor can be facet-grown by appropriately controlling growth conditions, and the shape of the seed crystal 2 can be the shape shown in FIGS. 5 and 6. For example, it is sufficient that the growth temperature is 1120°C to 1145°C, and a V/III ratio is 970 to 1020. In addition, since the shape is determined by selective growth, the shapes of the respective seed crystals 2 can be made uniform.

### 4. Initial Nucleus Formation Step S3

In the initial nucleus formation step S3 shown in FIG. 1, a mixed liquid containing the alkali metal melt prepared in the alkali metal melt preparation step S1 from which the oxygen atom has been removed and a Group III metal molten liquid is brought into contact with a surface of the seed crystal 2 in an atmosphere containing nitrogen, thereby forming initial nuclei 3 on various seed crystals 2 as shown in (b) of FIG. 3.

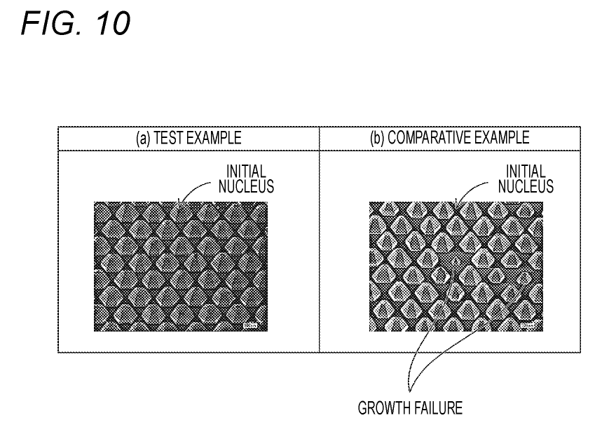

In the initial nucleus formation step S3, first, as shown in FIG. 7, a mixed liquid 101 containing the alkali metal melt from which the oxygen atom has been removed and a Group III metal molten liquid is stored in a crucible 100, and the seed substrate 9 is immersed in the mixed liquid 101 using a jig 400. Note that, as shown in FIGS. 7 to 9, the jig 400 is disposed inside the crucible 100 for growing a semiconductor single crystal by using a flux method, and can support the seed substrate 9 for growing a Group III nitride semiconductor single crystal inside the crucible 100. The jig 400 includes a first leg portion 401, a second leg portion 402, a third leg portion 403, a coupling portion 404, and a lifting shaft 405. A material of each member of the jig 400 is alumina. As shown in FIGS. 7 to 9, the first leg portion 401, the second leg portion 402, and the third leg portion 403 are each formed in a substantially rod shape, and as shown in FIG. 9, are suspended from corner portions of the coupling portion 404 having a substantially triangular flat plate shape in a plan view.

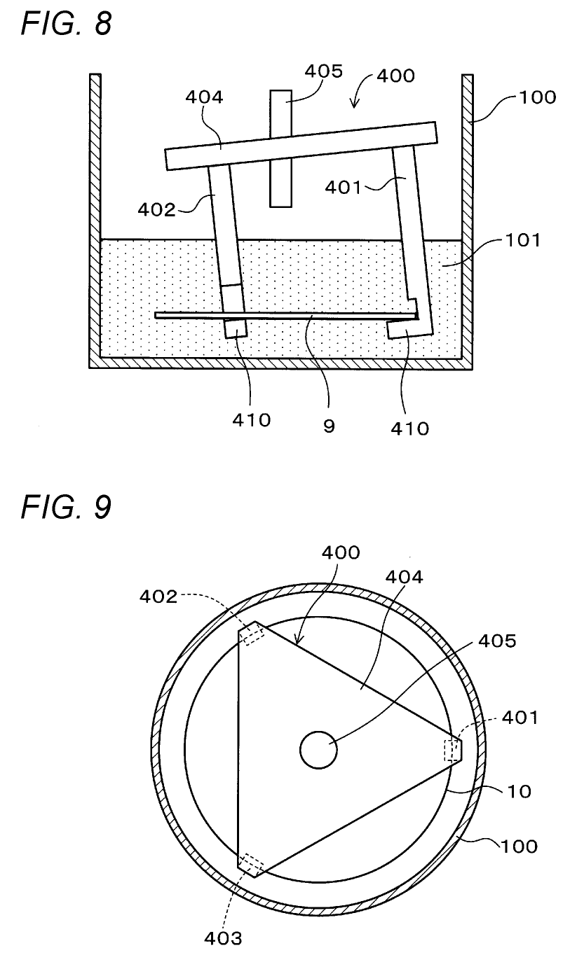

As shown in FIGS. 7 and 8, a substrate support portion 410 formed of a convex portion capable of supporting the seed substrate 9 is formed at a lower end of each of the first leg portion 401, the second leg portion 402, and the third leg portion 403 shown in FIG. 9. As shown in FIGS. 7 and 8, the first leg portion 401 is formed to be longer than the second leg portion 402 and the third leg portion 403 (not shown). Accordingly, the substrate 1 supported by the substrate support portion 410 is supported in a state of being inclined with respect to the coupling portion 404. The coupling portion 404 is connected to the lifting shaft 405 so as to be inclined with respect to the lifting shaft 405. Accordingly, the seed substrate 9 supported by the substrate support portion 410 is in a state of being inclined with respect to a horizontal direction as shown in FIG. 7 before being immersed in the mixed liquid 101 stored in the crucible 100, and is in a horizontal state as shown in FIG. 8 when being immersed in the mixed liquid 101 stored in the crucible 100.

In the initial nucleus formation step S3, next, an atmosphere in a furnace is substituted with an inert gas, the inside of the furnace is heated, and then evacuated to sufficiently reduce outgas components such as oxygen in the furnace.

Thereafter, predetermined amounts of Na and Ga are measured in the glove box 300 in which an atmosphere such as oxygen or a dew point is controlled. Thereafter, predetermined amounts of measured Na and Ga are charged into an empty crucible 100 (see FIG. 7) to form the mixed liquid 101. An additive element such as carbon may be added as necessary.

Next, the crucible 100 into which raw materials are charged and the seed substrate 9 are placed in a reaction vessel, which is then evacuated, and then a nitrogen-containing gas is supplied to the reaction vessel. When a pressure in the reaction vessel reaches a crystal growth pressure, a temperature of the furnace is increased to a crystal growth temperature. The crystal growth temperature is, for example, 700°C or higher and 1000°C or lower, and the crystal growth pressure is, for example, 2 MPa or more and 10 MPa or less.

When the inside of the reaction vessel reaches the crystal growth temperature and the crystal growth pressure and the nitrogen melted in the mixed liquid 101 is supersaturated, the seed substrate 9 is charged into the mixed liquid 101 in the crucible 100. Then, GaN crystals (initial nuclei 3) grow from the respective seed crystals 2 in the seed substrate 9. The growth of the initial nuclei 3 is performed until the adjacent initial nuclei 3 start to combine with each other (see (b) of FIG. 3). Note that, a gap remains between the initial nucleus 3 and the substrate 1.

Here, the side surface 2a of the regular hexagonal truncated pyramid portion of the seed crystal 2, that is, the (10-11) plane, is stably present in the mixed liquid 101 without being melted back. The seed crystal 2 has a height H1 of 30 μm or more, and the side surface 2a has a sufficiently large area. Therefore, the initial nucleus 3 grows from the side surface 2a while maintaining the (10-11) plane. Since the respective seed crystals 2 have a uniform shape and uniformly grow from the seed crystal 2 while maintaining the (10-11) plane, it is possible to prevent the variation in shape of the respective initial nuclei 3 and to make the shapes of the respective initial nuclei 3 uniform.

In addition, since the recess 2d is formed at the center of the seed crystal 2, the recess 2d is not completely filled with the initial nucleus 3, and the void 7 is formed. The mixed liquid 101 is confined in the void 7. Since the void 7 is formed in the upper portion of the seed crystal 2, it is possible to prevent the dislocation of the seed crystal 2 from being transferred to the upper portion.

In addition, by increasing the diameter of the recess 2d, the seed crystal 2 has a shape in which the upper surface (c plane) is not present. The c plane may be melted back in the mixed liquid 101 and is unstable. Since there is no crystal growth from such an unstable surface, the variation in shape of respective initial nuclei 3 can be further prevented. In addition, since there is no crystal growth from the c plane, it is possible to further prevent the dislocation of the seed crystal 2 from being transferred to the upper portion.

### 5. Crystal Growth Step S4

In the crystal growth step S4 shown in FIG. 1, a Group III nitride single crystal is grown from the initial nucleus 3 by bringing the mixed liquid 101 into contact with the initial nucleus 3 in an atmosphere containing nitrogen. In the present embodiment, the crystal growth step S4 includes the flattening step S41 and the film thickening step S42.

### 5-1. Flattening Step S41

The flattening step S41 is a step of growing a crystal by using an flux film coating (FFC) method, and is a step of repeatedly immersing the seed substrate 9 having the initial nucleus 3 formed thereon in the mixed liquid 101 stored in the crucible 100, pulling up the seed substrate 9 from the mixed liquid 101, and then heating the seed substrate 9 in a nitrogen atmosphere, to grow the GaN single crystal from the initial nucleus 3, to fill a space between the adjacent initial nuclei 3 with the GaN single crystal, and to flatten a crystal surface.

In the FFC method in the flattening step S41 according to the first embodiment, the seed substrate 9 is repeatedly taken out of the mixed liquid 101 as shown in FIG. 7, and immersed in the mixed liquid 101 as shown in FIG. 8, at a predetermined cycle. As shown in (b) of FIG. 3, when adjacent initial nuclei 3 begin to combine with each other, a groove 4 is formed on the combined surface. When the seed substrate 9 is taken out of the mixed liquid 101, the mixed liquid 101 is in a state of accumulating in the groove 4 between the adjacent initial nuclei 3. Accordingly, a crystal 5 can be grown along the groove 4 (see (c) of FIG. 6).

Here, since the mixed liquid 101 accumulated in the groove 4 has a small thickness, nitrogen is likely to be supersaturated. Therefore, the crystal growth rate can be increased. On the other hand, since the amount of the accumulated mixed liquid 101 is small, the amount of Ga is also small, and the crystal is not grown after a while. Therefore, the seed substrate 9 is immersed the mixed liquid 101 again as shown in FIG. 8, and the seed substrate 9 is taken out of the mixed liquid 101 again as shown in FIG. 7, whereby the mixed liquid 101 containing Ga is intermittently supplied to the groove 4. The FFC method is performed until the groove 4 is filled by the growth of the crystal 5. Accordingly, a crystal having a flat c plane can be grown.

### 5-2. Film Thickening Step S42

As shown in FIG. 1, the film thickening step S42 is performed after the flattening step S41. The film thickening step S42 is a step of forming a thick Group III nitride single crystal (GaN single crystal) 6 on the GaN substrate (seed substrate 9) by immersing the GaN substrate, which is the seed substrate 9 having the crystal surface flattened in the flattening step S41, in the mixed liquid 101 containing Ga and Na stored in the crucible 100.

In the film thickening step S42 according to the first embodiment, as shown in FIG. 8, the seed substrate 9 having a flat crystal surface is immersed in the mixed liquid 101 in a state of being supported by the substrate support portion 410, and when the GaN single crystal 6 is grown to a desired thickness, the temperature is lowered to room temperature, the pressure is also lowered to normal pressure, and the growth of the GaN single crystal 6 is completed. Note that, the duration of the film thickening step S42 can be appropriately set according to a target thickness of the GaN single crystal 6. Here, the gap between the initial nucleus 3 and the substrate 1 is not filled and remains. Therefore, the substrate 1 can be naturally peeled off when the temperature is lowered due to a difference in thermal expansion coefficient.

As described above, according to the GaN single crystal growth method in the first embodiment, the side surface 2a of the seed crystal 2 is the (10-11) plane. Therefore, the variation in shape of the respective initial nuclei 3 can be prevented, and a uniform and high quality GaN single crystal 6 can be formed.

In addition, the recess 2d is provided at the center of the seed crystal 2, and the seed crystal 2 has a shape in which the upper surface is not present. Therefore, the upper portion of the seed crystal 2 is not filled during the growth of the initial nuclei 3, and the void 7 is formed. As a result, the propagation of the dislocation of the seed crystal 2 to the upper portion can be prevented, and a high quality GaN single crystal 6 can be formed.

Note that, although the flattening step S41 based on the FFC method in the present embodiment is not necessarily performed, it is preferable to perform the flattening step S41 in order to further improve flatness of the crystal and further reduce the warpage.

### 6. Checking Test

Growth states of initial nuclei in a test example and a comparative example were compared using, as the test example, an alkali metal melt from which an oxygen atom had been removed by the Group III nitride single crystal growth method according to the first embodiment and using ,as the comparative example, an alkali metal melt from which an oxygen atom had not been removed. Note that, in the test example, the second temperature in the alkali metal melt preparation step S1 was set to 180°C. In the test example and the comparative example, the seed substrate 9 included the seed crystal 2 having a diameter in a range of 100 μm to 200 μm and a height of 5 μm to 40 μm. Note that, in the test example and the comparative example, the growth conditions of the initial nuclei other than the alkali metal melt were set the same.

In the test example using the alkali metal melt from which the oxygen atom has been removed, no growth failure of the initial nuclei is detected within a range photographed as shown in (a) of FIG. 10, but in the comparative example using the alkali metal melt from which the oxygen atom has not be removed, a plurality of growth failures of the initial nuclei are detected within a range photographed as shown in (b) of FIG. 10. A generation rate of the growth failure of the initial nuclei in the entire measurement range in the test example is about 1/10 of that in the comparative example. Accordingly, it is found that the growth failure of the initial nuclei can be prevented by removing the oxygen atom from the alkali metal melt.

### 7. Operations and Effects

Operations and effects of the Group III nitride single crystal growth method according to the first embodiment will be described below. According to the Group III nitride single crystal growth method in the first embodiment, an MPS substrate in which the Group III nitride semiconductor is formed in a plurality of dots on the substrate is used as the seed substrate 9, the Group III nitride semiconductor on the seed substrate 9 is used as the seed crystal 2, the mixed liquid 101 containing the alkali metal melt from which the oxygen atom has been removed and the Group III metal molten liquid is brought into contact with the surface of the seed crystal 2 to form the initial nucleus 3 on the seed crystal 2, and then the Group III nitride single crystal 6 is grown from the initial nucleus 3. Accordingly, since the alkali metal melt from which the oxygen atom has been removed is used, a degree of supersaturation of N (nitrogen) in the mixed liquid 101 can be increased without setting a low temperature and a high pressure, and the nucleation in the seed crystal 2 on the seed substrate 9 can be promoted while preventing the generation of miscellaneous crystals. As a result, the sizes or the shapes of the generated initial nuclei 3 can be made uniform, so that the generation of cracks or defects in the initial nuclei 3 or the Group III nitride single crystal 6 grown on the initial nuclei 3 is prevented, and the crystal quality can be improved.

In addition, in the present embodiment, in the alkali metal melt preparation step S1, the alkali metal melt is circulated through the first region 201 held at the first temperature and the second region 202 held at the second temperature lower than the first temperature, to remove the oxygen atom from the alkali metal melt in the second region 202. Accordingly, the nucleation in the seed crystal 2 on the seed substrate 9 as an MPS substrate is further promoted while preventing the generation of miscellaneous crystals, and the uniformity of the sizes or the shapes of the initial nuclei 3 to be generated can be further promoted. As a result, the crystal quality can be further improved.

In addition, in the present embodiment, in the alkali metal melt preparation step S1, the concentration of the oxygen atom in the alkali metal melt can be controlled by controlling the second temperature. Accordingly, the concentration of the oxygen atom in the alkali metal melt can be maintained at a low concentration, so that the generation of miscellaneous crystals can be prevented and the crystal quality of the Group III nitride single crystal 6 to be formed can be further improved.

In addition, in the present embodiment, the second temperature is controlled in a range of 120°C or higher and 300°C or lower, and the first temperature is controlled to a temperature higher than the second temperature. Accordingly, the oxygen atom can be removed while maintaining the fluidity of the alkali metal melt, so that the generation of miscellaneous crystals can be prevented and the crystal quality of the Group III nitride single crystal 6 to be formed can be further improved.

In addition, in the present embodiment, the oxygen concentration in the alkali metal melt is 30 ppm or less. Accordingly, the oxygen concentration in the alkali metal melt is sufficiently low, so that the generation of miscellaneous crystals can be further prevented and the crystal quality of the Group III nitride single crystal 6 to be formed can be further improved.

In addition, in the present embodiment, in the seed substrate preparation step S2, the diameter D1 of the seed crystal 2 formed on the substrate 1 is within a range of 30 μm to 300 μm. Accordingly, the Group III nitride single crystal 6 with little dislocation and warpage can be formed, the area of the side surface 2a of the seed crystal 2 can be increased, and the growth of the initial nucleus 3 from the side surface 2a can be facilitated.

As described above, according to the present embodiment, it is possible to provide a Group III nitride single crystal growth method capable of forming a Group III nitride single crystal having a high crystal quality using an MPS substrate.

The present invention is not limited to the above embodiment, and may be applied to various embodiments without departing from the gist of the present invention.

### REFERENCE SIGNS LIST

1: substrate

2: seed crystal

3: initial nucleus

6: Group III nitride single crystal (GaN single crystal)

9: seed substrate

100: crucible

101: mixed liquid

200: Na circulation device

201: first region

202: second region

210: supply tank

220: dump tank

230: cold trap

240: electromagnetic pump

250: expansion tank

260: measurement tank

270: Na collection port

281 to 283: pipe

290: heating device

300: glove box

400: Jig

What is claimed is:

1. A Group III nitride single crystal growth method comprising:
preparing an alkali metal melt from which an oxygen atom has been removed;
preparing a seed substrate in which a plurality of seed crystals made from a Group III nitride semiconductor are formed in a dot shape on a substrate;
forming an initial nucleus on the seed crystal by bringing a mixed liquid containing the alkali metal melt and a Group III metal molten liquid into contact with a surface of the seed crystal in an atmosphere containing nitrogen; and
growing a Group III nitride single crystal from the initial nucleus by bringing the mixed liquid into contact with the initial nucleus in an atmosphere containing nitrogen.

2. The Group III nitride single crystal growth method according to claim 1, wherein in the preparing of the alkali metal melt, the alkali metal melt is circulated through a first region held at a first temperature and a second region held at a second temperature lower than the first temperature, to remove the oxygen atom from the alkali metal melt in the second region.

3. The Group III nitride single crystal growth method according to claim 2, wherein in the preparing of the alkali metal melt, a concentration of the oxygen atom in the alkali metal melt is controlled by controlling the second temperature.

4. The Group III nitride single crystal growth method according to claim 2, wherein the second temperature is controlled in a range of 120°C or higher and 300°C or lower, and the first temperature is controlled to a temperature higher than the second temperature.

5. The Group III nitride single crystal growth method according to claim 3, wherein the second temperature is controlled in a range of 120°C or higher and 300°C or lower, and the first temperature is controlled to a temperature higher than the second temperature.

6. The Group III nitride single crystal growth method according to claim 1, wherein an oxygen concentration in the alkali metal melt is 30 ppm or less.

7. The Group III nitride single crystal growth method according to claim 2, wherein an oxygen concentration in the alkali metal melt is 30 ppm or less.

8. The Group III nitride single crystal growth method according to claim 3, wherein an oxygen concentration in the alkali metal melt is 30 ppm or less.

9. The Group III nitride single crystal growth method according to claim 1, wherein in the preparing of the seed substrate, a diameter of the seed crystal formed on the substrate is within a range of 30 μm to 300 μm.

10. The Group III nitride single crystal growth method according to claim 2, wherein in the preparing of the seed substrate, a diameter of the seed crystal formed on the substrate is within a range of 30 μm to 300 μm.

11. The Group III nitride single crystal growth method according to claim 3, wherein in the preparing of the seed substrate, a diameter of the seed crystal formed on the substrate is within a range of 30 μm to 300 μm.
